(19) United States
(12) Patent Application Publication
(10) Pub. No.: US 2021/0328021 A1
(43) Pub. Date: Oct. 21, 2021

(54) SYSTEMS AND METHODS FOR UNIVERSAL DEGENERATE P-TYPE DOPING WITH MONOLAYER TUNGSTEN OXYSELENIDE (TOS)

(71) Applicant: THE TRUSTEES OF COLUMBIA UNIVERSITY IN THE CITY OF NEW YORK, New York, NY (US)

(72) Inventors: James Hone, New York, NY (US); James T. Teherani, New York, NY (US); Ankur Baburao Nipane, New York, NY (US); Minsup Choi, New York, NY (US); Younghun Jung, New York, NY (US); Abhinandan Borah, New York, NY (US)

(73) Assignee: THE TRUSTEES OF COLUMBIA UNIVERSITY IN THE CITY OF NEW YORK, New York, NY (US)

(21) Appl. No.: 17/236,404

(22) Filed: Apr. 21, 2021

Related U.S. Application Data
(60) Provisional application No. 63/013,278, filed on Apr. 21, 2020.

(51) Int. Cl. H01L 29/167; H01L 29/16; H01L 29/24; H01L 21/04; H01L 21/385; H01L 51/00

(52) U.S. Cl. CPC H01L 29/167; H01L 29/1606; H01L 29/24; H01L 51/0074; H01L 21/385; H01L 51/002; H01L 51/0048; H01L 21/041

(57) ABSTRACT

Disclosed are compositions and methods of semiconductors including tungsten oxyselenide (TOS) as a p-type dopant. The TOS is formed by introducing a single layer of tungsten diselenide (WSe₂) to a semiconductor and subject the tungsten diselenide to a room-temperature UV plus ozone process. This process forms a TOS monolayer, which can be used as a universal p-type dopant for a variety of different semiconductors. Suitable semiconductor materials include, for example, graphene, carbon nanotubes, tungsten diselenide, and dinaphthothienothiophene (DNTT).

### CROSS-REFERENCE TO RELATED APPLICATIONS

This application claims priority to U.S. Provisional Patent Application No. 63/013,278, filed on Apr. 21, 2020, which is incorporated by reference herein in its entirety.

### GRANT INFORMATION

This invention was made with government support under 1752401 and 1420634 awarded by the National Science Foundation. The government has certain rights in the invention.

### BACKGROUND

Semiconductor doping can be used to make the junctions and contracts that are present in certain semiconductor devices. Doping is the introduction of a material to a semiconductor system to increase the number of free charges that are available to carry current. This doping process is used in many semiconductor technologies.

Certain semiconductor doping has been performed by introducing a specific impurity into a semiconductor crystalline lattice. This process can require high temperatures and the identification of specific dopant compounds to introduce into the material. As a result, dopants are not necessarily fully incorporated in the semiconductor crystalline lattice, which can result in damage or defect states created during the doping process. Further, certain dopants can become inactive at low temperatures due to an effect called “carrier freeze-out,” which can inhibit low-temperature operation.

Thus, there is a need for systems and methods which create stable doping patterns on a variety of semiconductor materials which reduce damage or defects on the resultant material and which can avoid the negative effects of carrier freeze-out.

### SUMMARY

The disclosed subject matter relates to systems and methods for performing p-type doping of semiconductors.

For instance, the presently disclosed subject matter includes a semiconductor including a tungsten oxyselenide (TOS) p-type dopant. In some embodiments, the TOS is formed by: (a) introducing a layer of tungsten selenide (WSe₂) to the semiconductor; and (b) oxidizing the layer of tungsten selenide to produce a layer of TOS. In some embodiments, the oxidizing process is performed at room temperature. In some embodiments, the oxidizing step includes UV-ozone oxidation. In some embodiments, the oxidizing process does not damage the semiconductor.

In some embodiments of the semiconductor including TOS, the layer of TOS is a monolayer. In some embodiments, the TOS is a p-type surface-layer dopant. In some embodiments, the semiconductor is a 1D semiconductor, a 2D semiconductor, or a 3D semiconductor. In some embodiments, the semiconductor is graphene, carbon nanotube, 4 L-tungsten diselenide, or dinaphthothienothiphene (DNTT).

Furthermore, the presently disclosed subject matter includes a method of doping a semiconductor, the method including: (a) providing the semiconductor; (b) introducing a layer of tungsten selenide (WSe₂) to the semiconductor; and (c) oxidizing the layer of tungsten selenide to produce a layer of tungsten oxyselenide (TOS). In some embodiments, the oxidizing process is performed at room temperature. In some embodiments, the oxidizing process includes UV-ozone oxidation. In some embodiments, the oxidizing process does not damage the semiconductor.

In some embodiments of the method of doping a semiconductor, the layer of TOS is a monolayer. In some embodiments, the TOS is a p-type surface-layer dopant. In some embodiments, the semiconductor is a 1D semiconductor, a 2D semiconductor, or a 3D semiconductor. In some embodiments, the semiconductor is graphene, carbon nanotube, 4 L-tungsten diselenide, or dinaphthothienothiphene (DNTT).

In certain embodiments, an exemplary method of doping can include oxidation of a single layer of tungsten diselenide (WSe₂) through a room-temperature UV plus ozone process. Tungsten diselenide is a semiconductor material that can exist as stacks of two dimensional (2D) sheets. The sheets can be weakly bonded in the out-of-plane direction. Through the UV plus ozone process, a single layer of tungsten diselenide can be oxidized to form a very thin (e.g. ˜1 nm) monolayer of tungsten oxyselenide (TOS). This layer can degenerately p-type dope a variety of different semiconductor layers beneath. For the purpose of example and not limitation, such doping can occur on carbon nanotubes, graphene, tungsten diselenide, and dinaphthothienothiophene (DNTT).

A variety of oxidation techniques are contemplated by the disclosed subject matter. For the purpose of example and not limitation, such techniques can include: ozone oxidation, O₂ plasma oxidation, O₂ thermal oxidation, H₂O “wet” oxidation, and H₂O₂ (hydrogen peroxide) oxidation treatment. Each of these exemplary techniques can be performed at a variety of temperatures.

TOS can act as a non-substitutional dopant, meaning that in certain embodiments it does not require a high-temperature process for activation and can be suitable for a variety of diverse semiconductor materials. Unlike certain doping systems and methods, the disclosed subject matter can provide for the oxidation of tungsten diselenide to TOS without damaging underlying semiconductor layers. In certain embodiments, the resultant doping material can remain stable and operate effectively at low temperatures (e.g. ˜1.5 K).

In certain embodiments, such doping can be stable for over a month, which can be useful for the creation of reliable semiconductor devices. This method can also create specific doping patterns, allowing for the creation of semiconductor device structures.

A variety of exemplary embodiments of the disclosed subject matter are contemplated. For the purpose of example and not limitation, such embodiments include, but are not limited to: doping of graphene sheets to create transparent conductive electrodes; use of doped 2D semiconductors and graphene in the creation of optical modulators; doping of 2D semiconductors to create PN junctions and/or improve contact resistance; doping of certain traditional semiconductors to improve contact resistant, create abrupt junctions, and/or allow operation at millikelvin temperatures.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1A shows device structure at different points in the measurement process. UV-ozone oxidizes monolayer WSe₂ creating monolayer TOS, which strongly p-type dopes the underlying graphene layer. The TOS-doping layer can be removed, if desired, with a 10-second dip in a dilute KOH solution. The sample is subsequently vacuum annealed at 300° C. to remove solvents from the surface.

FIG. 1B shows optical microscopic image of the Hall-bar device structure. S and D correspond to the source and drain contacts. The additional contacts are used for Hall-effect and four-probe (4p) measurements.

FIG. 2 shows optical microscopic images of WSe₂ with different thicknesses for pristine, after UV-ozone and after KOH. After UV-ozone, 1 L becomes barely visible. It is completely etched after KOH rinse while 2 L and 4 L are one-layer thinned to 1 L and 3 L demonstrating the layer-by-layer etching.

FIG. 3A shows four-probe (4p) resistance as a function of back-gate bias (V_{GS}) during the process.

FIG. 3B shows a zoomed-in view of sheet resistance (Rₛₕ) as a function of back-gate bias (V_{GS}) for the device before and after TOS doping.

FIG. 4 shows transfer curves of a 1 L-WSe₂ device before and after UV-ozone at V_{DS}=1 V. The Cr/Au contacts were formed by the edge contact method used for graphene devices. It shows an n-type semiconducting behavior before doping and the current drops to the noise floor of the measurement (grey line indicates the leakage current, I_{GS}) after doping.

FIGS. 5A and 5B show selected area electron diffraction (SAED) of monolayer WSe₂ before (FIG. 5A) and after (FIG. 5B) UV ozone. Single-crystal diffraction patterns with zone axis [0 0 0 1] are clearly visible before UV-ozone. The lack of crystalline points or rings after UV-ozone indicates that TOS is amorphous.

FIGS. 6A-6C show TEM and SAED pattern images. FIG. 6A shows a TEM image for monolayer and few-layer WSe₂. FIGS. 6B and 6C show corresponding SAED patterns for few-layer WSe₂ before and after UV-ozone treatment. Unlike monolayer WSe₂, few-layers still show single crystalline patterns even after UV-ozone treatment, indicating the underlying layers are protected by self-limited oxidation. The bottom table shows the obtained atomic percentage of W, Se and O atoms for monolayer and few-layer WSe₂ from EDS.

FIGS. 7A and 7B show energy band diagrams of TOS-doped graphene as separate layers in isolation (FIG. 7A) and in thermal equilibrium (FIG. 7B). The high work-function of TOS due to the defect states results in charge-transfer doping of graphene.

FIG. 8 shows tunable p-type doping in graphene with WSe₂ interlayers. Hole density as a function of back-gate bias, extracted from Hall-effect measurements. Increasing the number of WSe₂ interlayers between the TOS doping and graphene reduces the hole density in the graphene. Fermi-level energy of graphene in relation to its charge neutrality point (E_{CNP}), calculated from the extracted hole density. High hole doping densities push the Fermi-level deep into the valence band. The WSe₂ interlayers act as a pseudo-insulator since graphene is much more conductive.

FIG. 9 shows hysteresis of a 1 L-WSe₂/Gr device before and after UV-ozone. Double swept transfer curves of a 1 L-WSe₂/Gr device as-fabricated and doped at 290 K. Hysteresis is negligible after doping due to a surface cleaning effect by UV-ozone treatment.

FIGS. 10A-10C show transfer curves for graphene devices with WSe₂ interlayers. Transfer curves for graphene devices with 2 L-WSe₂ (FIG. 10A), 4 L-WSe₂ (FIG. 10B), and 5 L-WSe₂ (FIG. 10C) interlayers before and after doping.

FIGS. 11A and 11B show Hall mobility and sheet resistance for TOS-doped graphene. μ_{Hall} (FIG. 11A) and Rₛₕ (FIG. 11B) vs. V_{GS} at room temperature. With 3 L- and 4 L-WSe₂ interlayers, μ_{Hall} is >10,000 cm²/(V·s) and Rₛₕ is ˜48 Ω/sq.

FIGS. 12A and 12B show high hole mobility for TOS-doped graphene. FIG. 12A shows mobility as a function of hole density for TOS-doped graphene with 3 L- and 4 L-WSe₂ interlayers. Longitudinal-acoustic (LA) phonon-limited mobility is achieved at high hole densities in doped graphene, suggesting limited scattering due to the TOS doping. This extends the best hole mobility results, previously achieved in h-BN-encapsulated graphene, to higher hole densities. FIG. 12B shows mobility as a function of hole density for graphene with TOS and TOS with a 1 L-WSe₂ interlayer. At very high hole densities, the TOS doping shows a 12.5 mobility improvement compared to electrolyte gating, the only other technique able to achieve such high carrier densities.

FIGS. 13A and 13B show low temperature (1.5 K) measurements for TOS-doped graphene. The p (FIG. 13A) and μ_{Hall} (FIG. 13B) values were measured for TOS-doped graphene with different thicknesses of WSe₂ interlayers at 1.5 K. The p showed similar values to that obtained at 290 K. μ_{Hall} increased comparing to RT measurements due to a reduced phonon scattering.

FIG. 14 shows passivation effect by PMMA deposition. p at V_{GS}=0 V and RT for PMMA covered TOS-doped graphene. It shows a slight reduction of carrier density from 7 to 6×10¹² #/cm² after 4 weeks.

FIG. 15A shows reduction in graphene absorption with TOS doping. The figure shows absorption spectrum of CVD-grown WSe₂ on graphene before (undoped) and after the UV-ozone oxidation (TOS-doped), measured by differential reflectance. The dashed line indicates the absorption of intrinsic graphene (2.3%). Before UV-ozone oxidation, an absorption peak is seen at 1.67 eV, corresponding to the excitonic band gap of monolayer WSe₂, and the absorption remains around graphene intrinsic absorption for photon energies less than 1.2 eV. After UV-ozone oxidation, the WSe₂ peak disappears, and absorption is reduced by ˜75% compared to intrinsic graphene at telecommunication wavelengths. The insets show different CVD stacks on quartz substrate to compare transparency.

FIG. 15B shows optical absorption at telecom wavelengths as a function of sheet resistance for widely-used transparent conducting films. The thickness of the films is indicated in parentheses. TOS-doped graphene are highlighted in purple and red and show the lowest absorption for a given sheet resistance, remarkable considering their <5-nm film thickness.

FIGS. 16A-16C show universal p-type doping of semiconductors with TOS. Current as a function of back-gate bias for a SWCNT (FIG. 16A), multilayer WSe₂ (FIG. 16B), and DNTT (FIG. 16C) with and without TOS doping. The insets show the structure of each device.

FIGS. 17A and 17B show SEM and optical microscopic images for a SWCNT device. FIG. 17A shows a SEM image to show a SWCNT grown from a metal seed. FIG. 17B shows optical microscopic images for the fabricated device based on the position of SEM image with transferred WSe₂. After UV-ozone, the WSe₂ became barely visible indicating a formation of TOS layer.

FIGS. 18A-18C show electrical characterization of TOS-doped WSe₂. FIGS. 18A and 18B show p (FIG. 18A) and μ_{Hall} (FIG. 18B) vs. Vis for a doped 4 L-WSe₂ device. The channel layer became 3 L since topmost layer became TOS after UV-ozone treatment. p vs. V_{GS} shows sub-linear behavior and 5.1×10¹² #/cm² at V_{GS}=0 V. FIG. 18C shows 2R_{c} vs. V_{GS} at V_{DS}=0.1 V before and after UV-ozone. R_{c} is decreased by at least 20-fold due to the doping effect.

FIGS. 19A-19B show schematic diagrams and optical images for a DNTT device. FIG. 19A shows 1 L-WSe₂ prepared on a SiO₂/Si substrate by mechanical exfoliation. FIG. 19B shows that after UV-ozone treatment, DNTT layer was deposited by sublimation. To define the channel area, it was patterned by e-beam lithography following SF₆ plasma etching. PMMA layer for the patterning was not removed to protect the channel organic layer.

FIGS. 20A-20C show optical response of TOS-doped graphene. FIG. 20C shows transmittance of CVD-grown 1 L-WSe₂ on graphene before and after the UV-ozone oxidation. Shaded area indicates the standard deviation. The dashed line indicates the transmittance of intrinsic graphene (97.7%). The insets show different CVD stacks on quartz substrate to compare transparency in visible regime. FIG. 20B shows top-view and cross-sectional schematics of a microring resonator with TOS(WSe₂)/Gr/h-BN composite stack on planarized SiN waveguide. FIG. 20C shows Normalized resonator transmission spectra of the planarized SiN ring configuration before transfer (blue), after transfer (grey) and after UV-ozone oxidation (red) of the stack.

### DETAILED DESCRIPTION

The disclosed subject matter provides a semiconductor doped with tungsten oxyselenide (TOS) as a p-type dopant, as well as methods of producing the same.

Traditional semiconductor dopants are substitutional, where a dopant atom takes place of a host atom in a semiconductor crystal. Substitutional dopants must be tailored for each semiconductor material and require a high annealing temperature (e.g., at least 400° C.) to activate the dopants. Substitutional dopant concentration is also limited by the solid solubility of the material, which places an upper bound on the maximum doping concentration that can be obtained.

In contrast, the semiconductors disclosed herein are doped with TOS. TOS can be used as a monolayer p-type dopant. The method of doping a semiconductor with TOS is advantageously performed through a gentle UV-ozone oxidation process. Tungsten diselenide (WSe₂), a 2D layered semiconductor, is UV-ozone oxidized to form TOS. The oxidation process occurs at room temperature and can therefore be used without destroying or damaging temperature-sensitive materials. The WSe₂ can be subject to UV-ozone oxidation at room temperature for, e.g., about 30 minutes. Optionally, the TOS layer can be removed after oxidation with potassium hydroxide followed by a vacuum anneal. Removal of the TOS layer after the oxidization process shows that the semiconductor is not damaged by the oxidation process.

TOS can have a low sheet resistance at room temperature, e.g., about 118 Ω/sq without any interlayers, or e.g., about 48 Ω/sq with 3 L- and 4 L-WSe₂ interlayers. Furthermore, monolayer TOS can induce a high hole doping density of 3.2×10¹³ #/cm², which is outside the range of typical doping techniques. Existing techniques to achieve high carrier densities that are based on chemical doping, electrolyte gating, and light and plasma exposure can cause significant material degradation. Additionally, these techniques result in low mobility and observation of D-band peaks in Raman measurements, indicative of defects after doping.

Furthermore, TOS doping remains active at very low temperatures. Traditional dopants require high temperatures to activate them. Traditional dopants can also experience “carrier freeze-out” at lower temperatures and become inactive. TOS, on the other hand, does not suffer from these drawbacks and is active at temperatures as low as, e.g., 1.5 K.

TOS is also advantageous over traditional dopants because traditional dopants only work for specific semiconductors and thus need to be tailored to the semiconductor being used. TOS, on the other hand, can be used as a universal dopant with any semiconductor that is known in the art. This is because TOS can lie on the surface of the semiconductor as opposed to being incorporated in the lattice, and thus can be used on a variety of different semiconductors. For example, semiconductors that are suitable for use with TOS as a dopant include 1D semiconductors, 2D semiconductors, and 3D semiconductors. The semiconductor can be, for instance, graphene, carbon nanotube, 4 L-tungsten diselenide (4 L-WSe₂), or dinaphthothienothiphene (DNTT). In some embodiments, the semiconductor is graphene. In some embodiments, the semiconductor is carbon nanotube, e.g., single-walled carbon nanotube. In some embodiments, the semiconductor is DNTT. Semiconductors that can be used as disclosed herein can be produced according to any suitable methods known in the art.

A semiconductor having a TOS dopant can be used in any commercial applications as known in the art. For example, a semiconductor having a TOS dopant can be used in photonic applications for telecommunications.

The UV-ozone oxidation process used to form TOS can also be used to create monolayer dopants from other 2D transition metal dichalcogenides (TMDCs). For example, molybdenum disulfide (MoS₂) and molybdenum diselenide (MoSe₂) are also suitable for UV-ozone oxidation to form a dopant. As discussed above, UV-ozone oxidation is advantageous for doping semiconductors because it uses a gentle process that can take place at room temperature, thereby avoiding causing damage to temperature-sensitive materials. Thus, MoS₂ and MoSe₂ can also be oxidized to create a semiconductor dopant that has similar doping properties as TOS as described herein.

### Example 1. Tungsten Oxyselenide (Tos) as a P-Type Surface-Layer Dopant

Monolayer tungsten oxyselenide (TOS) is used in this example as a p-type surface-layer dopant. Monolayer TOS is formed by the room-temperature UV-ozone oxidation of monolayer WSe₂, a 2D layered semiconductor. TOS is not a substitutional dopant so it does not require a high-temperature process for activation and is suitable for a variety of diverse semiconductor materials, as will be shown. Moreover, monolayer TOS can induce an incredibly high hole concentration of 3.2×10¹³ #/cm², outside the reach of typical doping techniques.

Monolayer graphene is used to illustrate the doping properties of monolayer TOS. Details regarding the methods used in this experiment are provided below in Example 2. Graphene has been extensively studied for the past decade for applications in high-speed electronics and photonics due to its extremely high carrier mobility and unique optical properties such as universal light absorption independent of wavelength. Its high conductivity relative to its atomic-layer thickness also creates opportunities for its use as a transparent and flexible electrode. Both applications inevitably require high doping density to achieve high conductivity as well as low absorption of the light. In addition, previous reports of correlated states in 2D materials have been limited by the carrier densities that researchers could obtain using electrostatic gating. High carrier densities obtained by doping that preserves the integrity of the material would allow investigation into correlated states that cannot currently be accessed at lower carrier densities. However, existing techniques to achieve high carrier densities—based on chemical doping, electrolyte gating, and light and plasma exposure—cause significant material degradation, attributed to charge impurities and increased disorder. These existing techniques result in low mobility and observation of D-band peaks in Raman measurements, indicative of defects after doping. Thus, the development of nondamaging and controllable doping is highly desired for graphene and other semiconducting materials for both physics and engineering fields. The TOS doping at the center of this work overcomes the aforementioned limitations, potentially enabling new scientific discoveries.

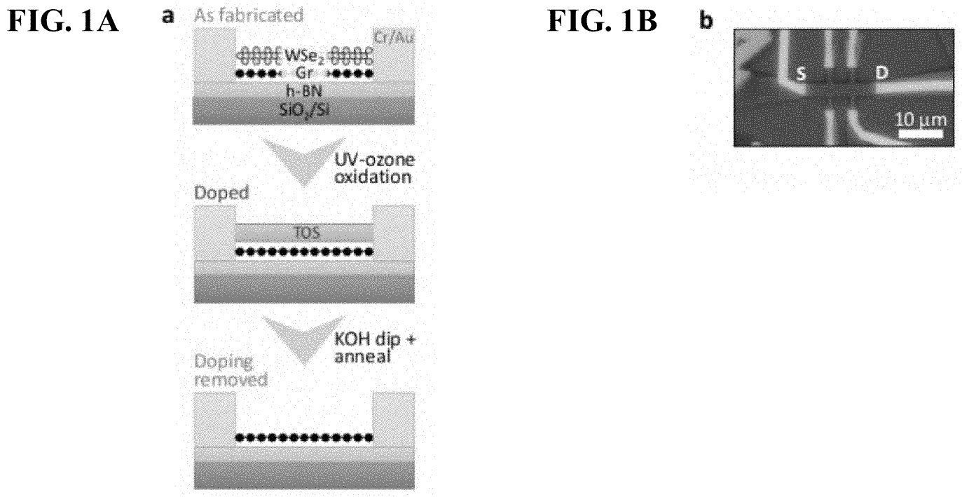

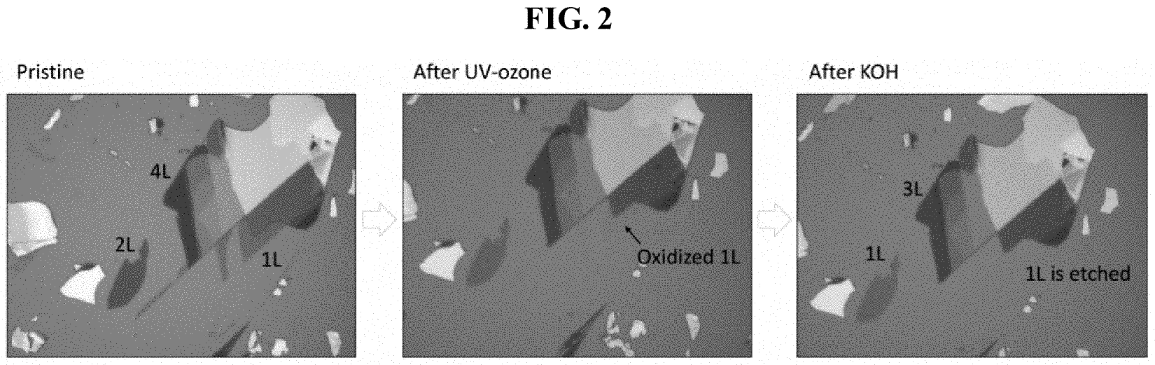

FIG. 1A shows the process for TOS doping of a monolayer graphene device. The initial sample is prepared using the dry transfer process for creating stacks of 2D materials using polycaprolactone (PCL) polymer. The device is etched into a Hall-bar to allow subsequent 4-terminal and mobility measurements and metal contacts are formed as shown in optical image of FIG. 1B. In the as-fabricated device structure, the monolayer of semiconducting WSe₂ is much more resistive than graphene and, hence, graphene dominates the electrical characteristics. The monolayer WSe₂ is transformed into TOS by 30 minutes of room-temperature UV-ozone oxidation and the device is measured. The device is characterized again after the TOS-doping layer is removed using a 10-second potassium hydroxide (KOH) dip followed by a vacuum anneal at 300 C for 30 minutes that eliminates solvent residue. The results after TOS removal show that the underlying graphene is not damaged during the UV-ozone oxidation or KOH processes. The optical microscopic images for each step are shown in FIG. 2, and detailed procedures steps for stacking, doping, and etching are provided in the Methods section provided below in Example 2.

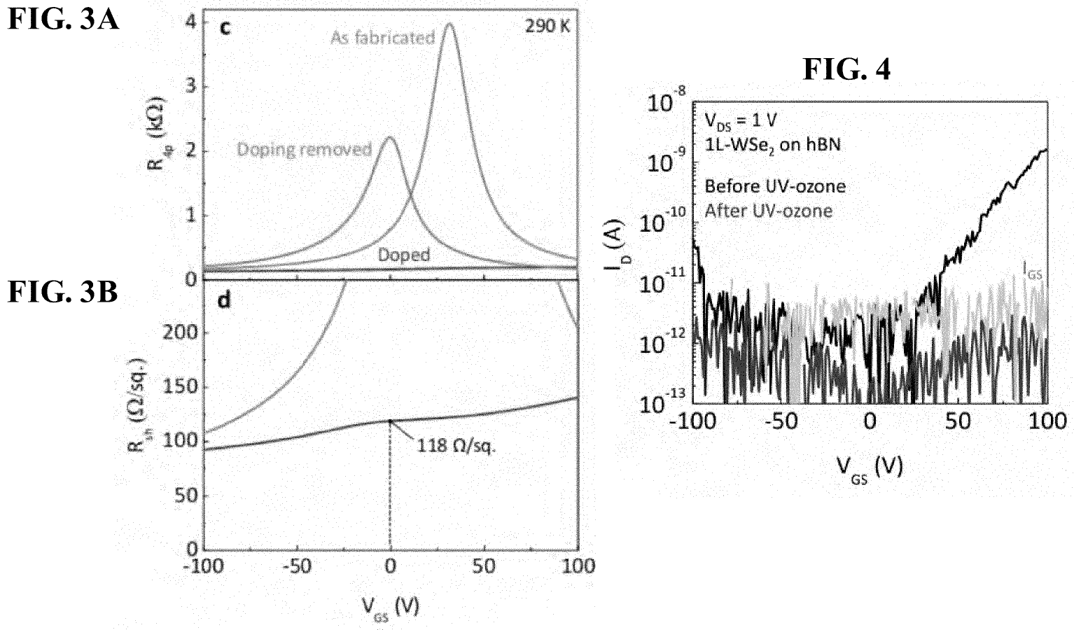

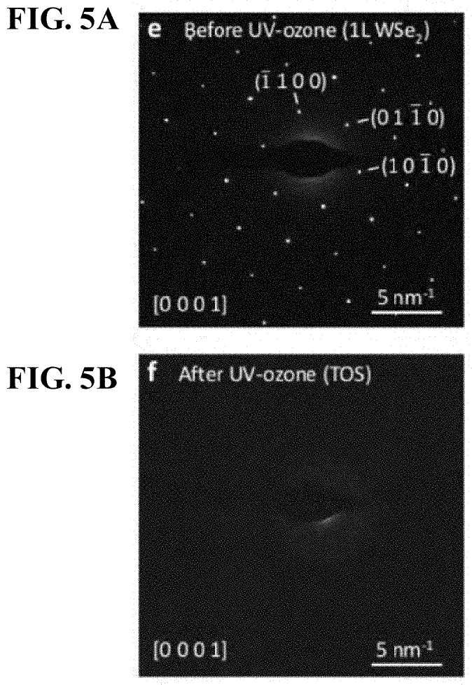

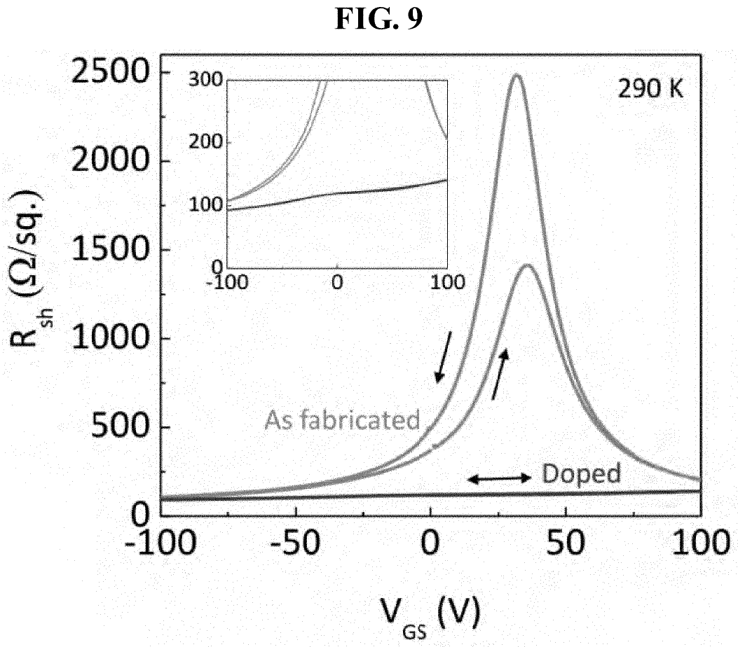

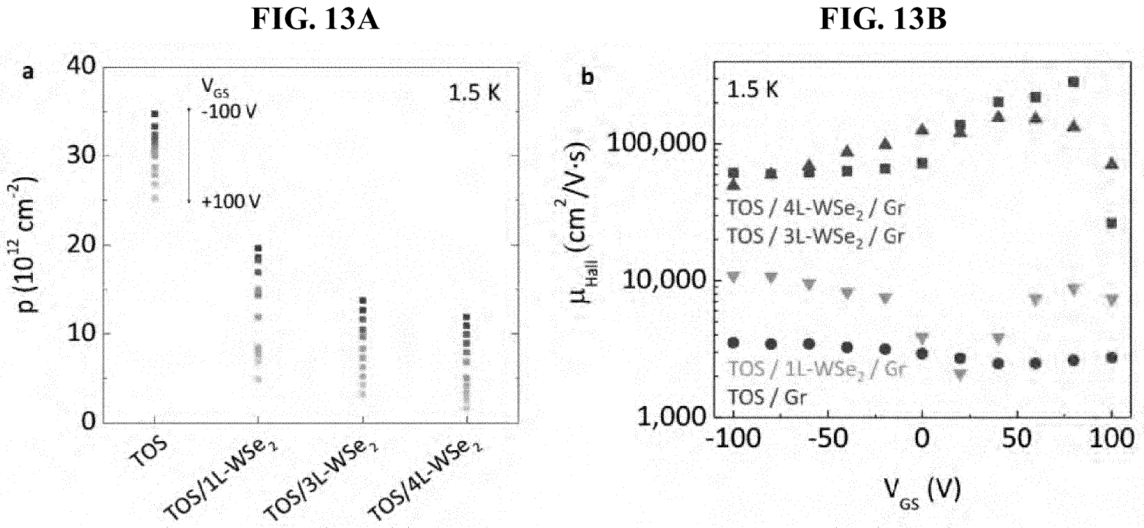

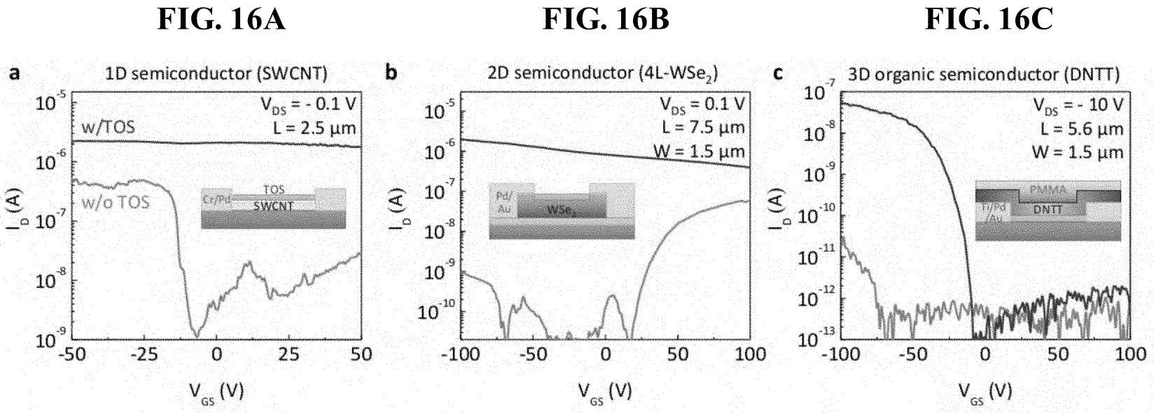

The four-probe (4p) resistance measurement elucidates the doping effects as shown in FIG. 3A. Before doping, the Dirac point—the bias at which there is equal densities of electron and holes in the graphene—is at VGS=+30 V while it completely disappears (within the measurement range) after doping indicating an ultrahigh carrier density in graphene. The 4p resistance increases with larger positive gate voltages and decreases with larger negative voltages implying the induced carriers are p-type. To exclude the possibility that monolayer TOS itself is conductive, a monolayer WSe₂ device was fabricated and measured before and after UV-ozone oxidation (FIG. 4). After oxidation, the current across TOS is ˜1 pA, which is the measurement system's noise floor. Thus, current is only carried in the underlying graphene layer. This conclusion is further corroborated by the graphene carrier density and mobility extraction in FIGS. 8 and 12A-12B, discussed in further detail below. After removal of the TOS-doping layer, the electrical characteristics of pristine graphene are recovered with a Dirac point at ˜0 V. FIG. 3B shows the sheet resistance dependence on back-gate bias (VGS). Graphene doped with monolayer TOS had an extremely low sheet resistance of 118 Ω/sq for zero gate bias at 290 K. For comparison, the sheet resistance of this two-atomic-layer TOS/graphene stack is comparable to that of a 50-nm-thick indium-tin-oxide (ITO) film, the most commonly used transparent conductor. Furthermore, the stack has 50-times lower sheet resistance than a recently demonstrated 3-nm thick 2D ITO, and it is superior to other graphene-related transparent conductors at similar thicknesses. Comparison to other transparent conductors is further discussed below in relation to absorption in FIG. 15B.

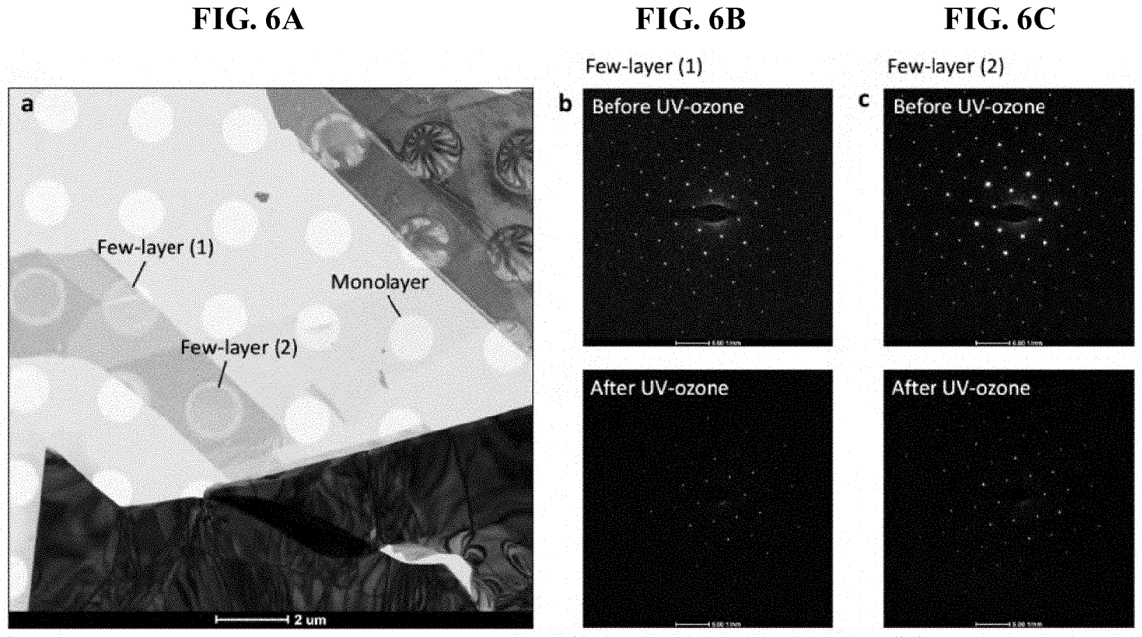

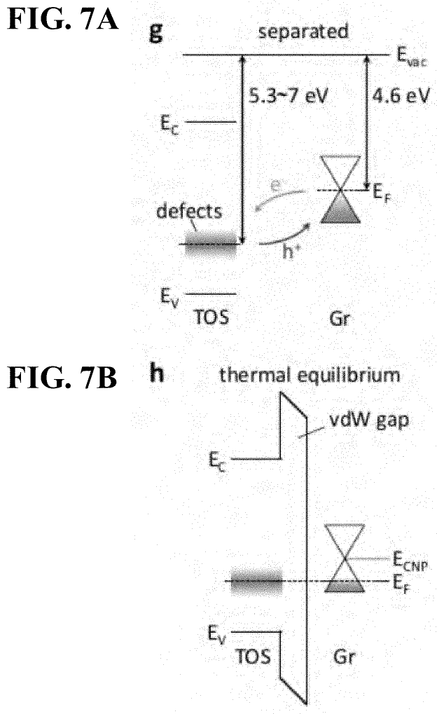

Selected area electron diffraction (SAED) was used to measure transformation in crystal structure of WSe₂ before and after UV-ozone oxidation, as shown in FIGS. 5A and 5B. The transmission electron microscope (TEM) image, SAED patterns of few-layer WSe₂, and energy-dispersive X-ray spectroscopy (EDS) results after UV-ozone are included in FIGS. 6A-6C and Table 1. Table 1 shows atomic percentage of mono- and few-layer WSe₂ from EDS. The table shows the obtained atomic percentage of W, Se and O atoms for monolayer and few-layer WSe₂ from energy-dispersive X-ray spectroscopy (EDS). It is noted that the atomic ratio of W and Se is approximately 1:2 for the few-layer WSe₂ since the underlying layers are preserved while the atomic percentage of Se for monolayer is significantly reduced (although not completely removed and therefore, denoted as TOS) by the oxidation process.

TABLE 1
Atomic percentage of mono-
and few-layer WSe₂ from EDS.
Atomic percentage after UV-
ozone treatment from EDS

| Mono-layer WSe₂ | | | Few-layer WSe₂ | | |
|---|---|---|---|---|---|
| W | Se | O | W | Se | O |
| 0.55 | 0.38 | 4.2 | 0.98 | 2.09 | 3.46 |

Single-crystal patterns of WSe₂ with a [0 0 0 1] zone axis are clearly seen before UV-ozone. By contrast, the diffraction pattern becomes dark after UV-ozone indicating that TOS is amorphous. The diffraction pattern for few-layer WSe₂ shown in the supplement still shows single-crystal patterns demonstrating that the underlying layers are protected due to the self-limited oxidation. EDS confirms the existence of selenium atoms after UV-ozone oxidation of monolayer WSe₂, suggesting a composite form of tungsten oxyselenide as WSe_{0.7}Oₓ, which is denoted as simply TOS. The X-ray photoelectron spectroscopy (XPS) results disclosed in Nipane, A. et al. Atomic Layer Etching (ALE) of WSe₂ Yielding High Mobility p-FETs. In 2019 Device Res. Conf., 2013, 231-232 (IEEE, Ann Arbor, 2019) (Ref. 16; incorporated herein by reference) suggest an oxygen stoichiometry (x) between 2 and 3, but more work is needed to accurately determine the precise stoichiometry.

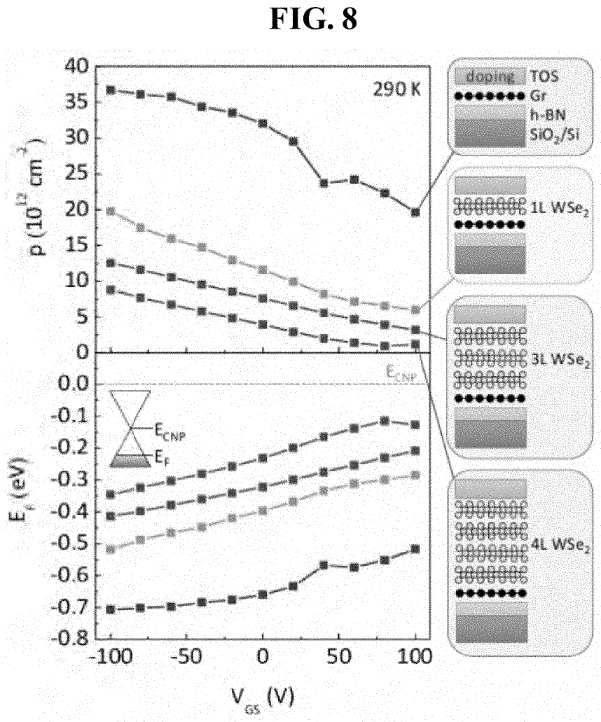

FIG. 7A shows the predicted energy band alignment for TOS and monolayer graphene. A high work-function for TOS was expected. After TOS and graphene are joined, charge transfer occurs resulting in strong p-type doping in graphene (FIG. 7B). The charge-transfer doping of TOS prevents damage to the underlying material resulting in high-quality p-type doping with remarkably high mobility and low sheet resistance as will be discussed in the following sections.

Using Hall-effect measurements, the hole density of graphene with TOS was extracted at different backbias as shown in FIG. 8. At zero gate bias, a highly degenerate hole density of 3.2×10¹³ #/cm² was measured for a monolayer TOS doped graphene (red plot). This high doping density is not easily achieved with certain conventional electrostatic gating techniques due to dielectric breakdown. For example, an ideal metal gate with a perfect dielectric (i.e., no defects, no leakage current, and a high electrical-breakdown dielectric strength of 1 V/nm) can only accumulate ˜2×10¹³ #/cm² before catastrophically failing; however, in practice, the maximum hole density obtained by electrostatic gating is typically much smaller due to large leakage currents that flow through the gate dielectric when high fields are applied. High hole densities can be obtained by electrolyte gating; however, electrolyte gating is dirty, hysteretic, sensitive to environments and unsuitable for manufacturing.

In addition, the hole density achieved with TOS doping is equivalent to approximately 1% of the graphene atomic density (3.82×10¹⁵ #/cm²), which is comparable with state-of-the-art silicon doping techniques. The percentage is comparable to the maximum limit of heavily-doped silicon (0.6˜1.2%) by various substitutional doping techniques. However, in contrast to substitutional doping, TOS doping does not modify the constituent atoms of the crystal, allowing researchers study its innate properties, albeit at a much larger hole density.

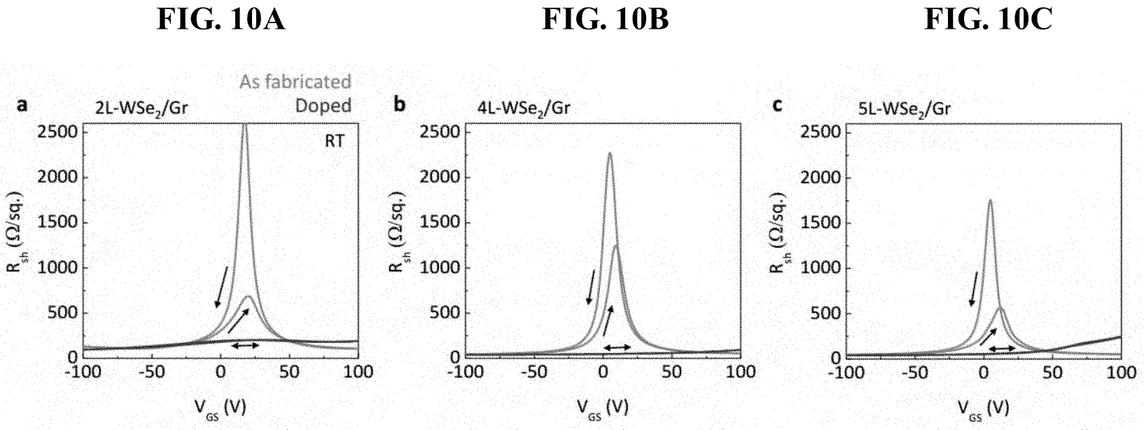

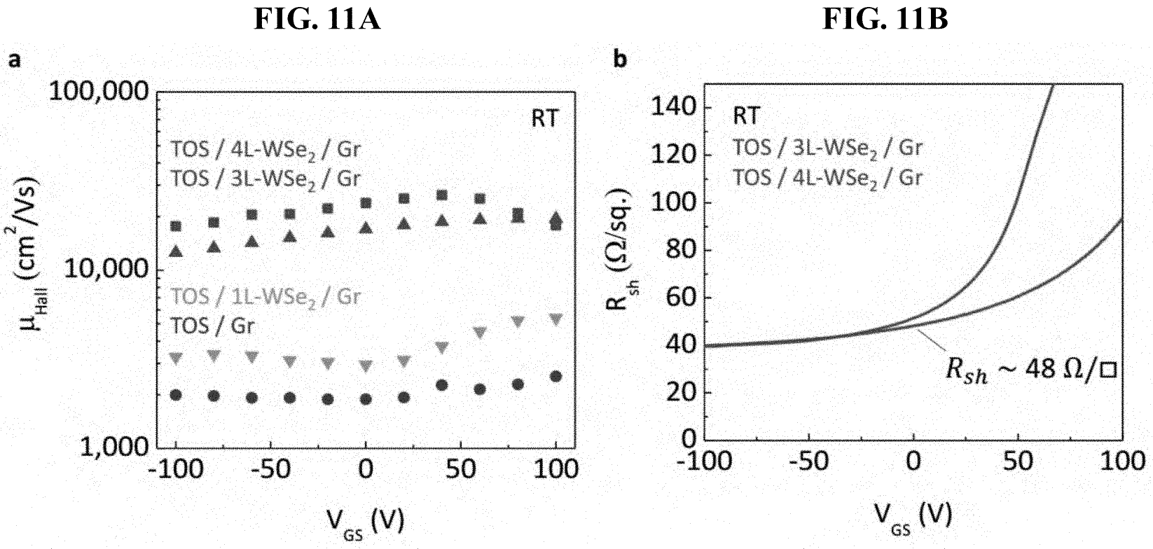

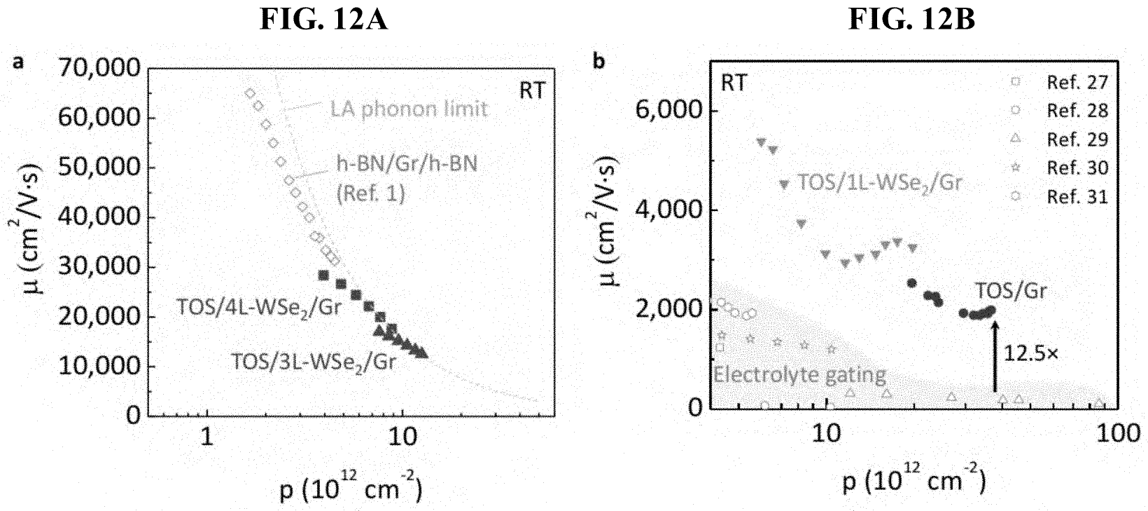

The dry transfer process enables us to use interlayers between the TOS doping and the graphene channel to adjust the doping density by ˜10-fold. Since graphene is much more conductive than WSe₂, the WSe₂ interlayers act as a pseudo-insulator with only a small fraction of the total current flowing through them. As the initial layer (L) thickness of WSe₂ was varied from 1 L to 5 L (which becomes 0 L to 4 L after UV-ozone doping since the topmost layer is oxidized into TOS), the zero-bias hole density in graphene decreases from 3.2 to 0.4×10¹³ #/cm². Sheet resistance for each device before and after UV-ozone doping are shown in FIGS. 9 and 10A-10C. The resistance drops from 118 Ω/sq for the device without any interlayer to 48 Ω/sq for a device with 3 L- and 4 L-WSe₂ interlayers. Although counter-intuitive, as the doping density decreases in the graphene for the latter case, this decrease in the sheet resistance arises due to the increase in the mobility. Amorphous TOS possibly induces scattering in direct contact with the graphene while the crystalline WSe₂ facilitates passivation of the underlying layer leading to reduced scattering and, thus, higher mobility as shown in FIGS. 11A and 11B.

The Fermi-level energy (E_{F}) in the graphene is related to its hole density (p) by

E_{CNP}−E_{F}=hv_{F}\sqrt{πp},

where E_{CNP} is the energy of charge neutrality point in graphene, h is the reduced Planck constant, and V_{F} is the Fermi velocity of graphene (10⁶ m/s). Depending on the WSe₂-interlayer thickness and the applied V_{GS}, the Fermi-level of the TOS-doped graphene lies between 0.1 and 0.7 eV below the charge neutrality point. At the highest doping densities (i.e., without any WSe₂ interlayers), the Fermi level is deep into the graphene valence band, which prevents graphene from effectively absorbing light for photon energies less than twice the Fermi-level difference from the charge neutrality point (i.e., Eₚₕ<2×|E_{CNP}−E_{F}|). For the highest doping, this suggests that photons with energies much less than 1.4 eV (or, equivalently, wavelengths much longer than 885 nm) will have negligible absorption due to interband transitions and, instead, be limited by intraband transitions and scattering. This suggests potential use of TOS-doped graphene as a transparent conductor in photonic applications for telecommunications at λ=1550 nm. The absorption spectrum of graphene before and after TOS doping is further discussed below in FIGS. 15A-15B.

The damage-free nature of TOS doping is indicated by the high hole mobilities extracted through Hall measurements, shown in FIG. 12A. For a reference, the plot shows the carrier mobility for an ideal h-BN-encapsulated graphene device that represents the highest mobility that has been previously achieved. When viewed together, the results for TOS-doped graphene with WSe₂ interlayers extend the mobility trend discussed in Wang, L. et al. One-Dimensional Electrical Contact to a Two-Dimensional Material. Science 342, 614-617 (2013) (Ref 1; incorporated herein by reference) to higher hole densities that were previously not obtainable. Furthermore, the mobility for TOS-doped graphene with 3 L- and 4 L-WSe₂ interlayers almost perfectly fits the longitudinal-acoustic (LA) phonon scattering limit as indicated by gray dashed line. This suggests minimal scattering due to the TOS doping and nearly intrinsically-limited transport in the graphene layer.

Previously, high carrier densities were difficult to achieve without the use of electrolyte gating. In FIG. 12B, the hole mobilities achieved with electrolyte gating at high hole densities is compared to the results with TOS doping. The hole mobility for TOS-doped graphene is shown to be higher than electrolyte gating across the measured hole density range, with a 12.5 improvement in mobility at p 4×10¹³ #/cm². Although electrolyte gating can induce a wide range of carrier densities, the ionic liquid introduces charged impurities that limit mobility, even at room temperature (RT). In contrast to electrolyte gating, charge impurity scattering seems to be less dominant with TOS doping giving rise to the higher mobility. The hysteresis is also significantly suppressed after doping as shown in FIGS. 9 and 10A-10C.

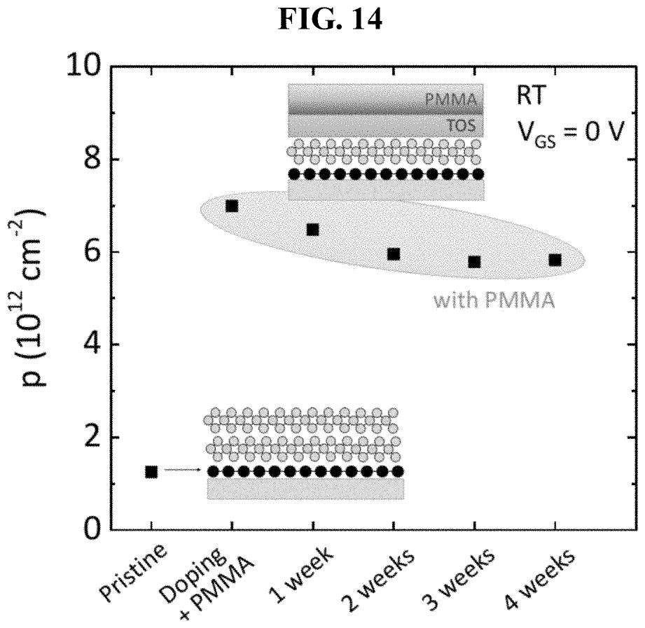

Device operation at cryogenic temperatures less than 4 K is of great interest for fundamental physics and exploring quantum systems, including quantum computing. To test if the TOS doping remains active at low temperature, the devices were measured at 1.5 K. As shown in FIG. 13A-13B, the hole density at 1.5 K is similar to that obtained at room temperature proving that the doping remains active across the entire temperature spectrum. At low temperature, the Hall mobilities increase due a reduction in phonon scattering. With a 3 L-WSe₂ interlayer, the hole mobility reaches 120,000 cm²/(V·s) at p=8.3×10¹² #/cm².

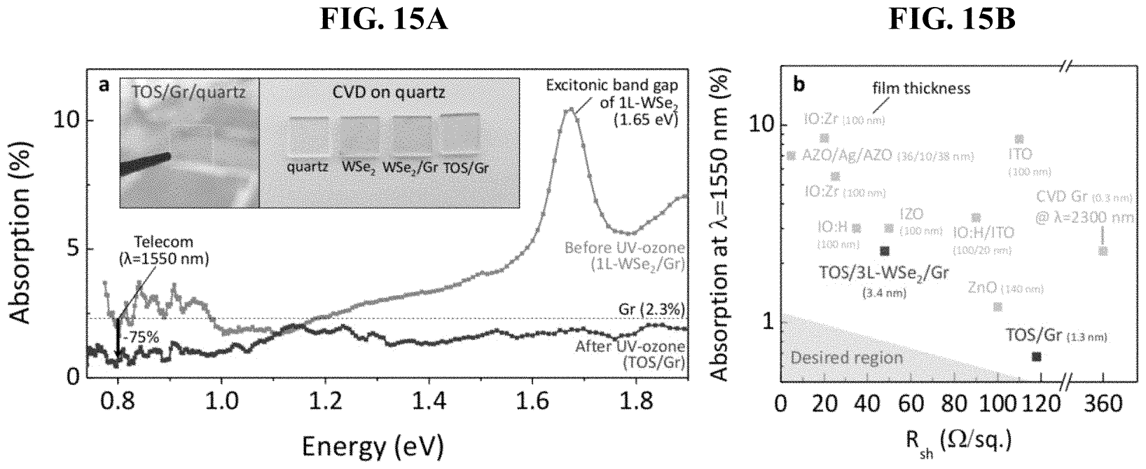

The high doping density of TOS can be degraded by air exposure due to its hydrophilic surface that tends to absorb water and oxygen molecules. In FIG. 14, the stability of TOS doping is demonstrated by encapsulating it with PMMA polymer. The device was measured immediately after PMMA spin coating and the subsequently each week for four weeks, while being kept in a nitrogen dry box in-between measurement. The nitrogen dry box was frequently opened and accessed by other lab users during the four-week testing period. The zero-bias hole density is shown to only change slightly from 7 to 6×10¹² #/cm² after four weeks of measurements. These results provide indication that encapsulation and passivation techniques can be further developed to maintain the integrity of the TOS-doping layer over long durations.

To demonstrate the potential of TOS-doped graphene as a transparent conductor, the absorption spectrum of chemical vapor deposition (CVD)-grown WSe₂ on graphene directly on quartz before (undoped) and after UV-ozone oxidation (TOS-doped) was measured as shown in FIG. 15A. Before UV-ozone oxidation, an absorption peak occurs at the excitonic band gap of WSe₂ (1.67 eV), perfectly matched with previous reports, and the absorption hovers around graphene's intrinsic absorption value for photon energies less than 1.2 eV. The absorption peak disappears after WSe₂ is transformed into TOS through UV-ozone oxidation, and absorption for photon energies less than 1.1 eV decreases below the value for intrinsic graphene. The TOS-doped graphene is more transparent than other CVD-grown WSe₂ and WSe₂/graphene as shown in the insets indicating the decreased absorption even in the visible range. The shift in the graphene Fermi level deep into the valence band due to TOS doping reduces absorption for photon energies less than twice the Fermi-level difference from the charge neutrality point (i.e., Eₚₕ<2×|E_{CNP}−E_{F}|). From the absorption data, it is inferred that the Fermi level of the TOS-doped graphene is around 0.55 eV below the charge neutrality point of graphene, in reasonable agreement with 0.65 eV value determined from electrically measured hole density.

Furthermore, the TOS doping significantly reduces optical absorption to 0.67% at telecommunication wavelengths (λ˜1550 nm), demonstrating its potential as a transparent conductor for photonic applications. FIG. 15B compares this work to widely-used transparent conducting films, including CVD graphene (measured at 2300 nm), ITO, zinc-doped indium oxide (IZO), zirconium-doped indium oxide (IO:Zr), hydrogen-doped indium oxide (IO:H), zinc oxide (ZnO), and an aluminum-doped zinc oxide and silver heterostructure (AZO/Ag/AZO). This work's results for TOS/graphene and TOS/3 L-WSe₂/graphene give the smallest optical absorption at 1550 nm at a given sheet resistance (0.67% absorption at 118 Ω/sq and 2.3% absorption at 48 Ω/sq, respectively). The very low absorption makes TOS-doped graphene particularly appealing for use as a transparent gate electrode near optical waveguides and as a high-speed phase-modulator for IR photonics.

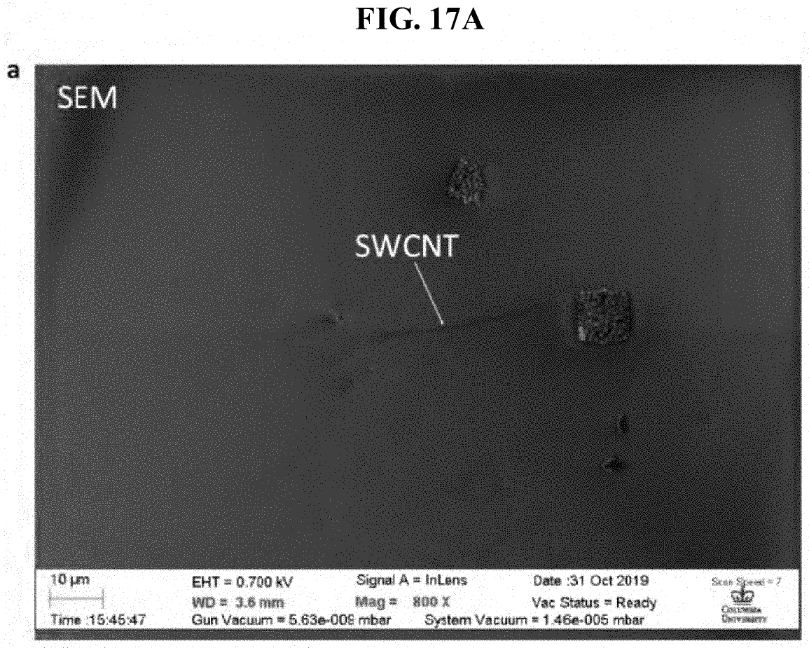

To show its universality as a p-type semiconductor dopant, devices with and without TOS doping were built from a 1D semiconductor (SWCNT, single-walled carbon nanotube), 2D semiconductor (4 L-WSe₂), and 3D organic semiconductor (DNTT, dinaphthothienothiophen) shown in FIGS. 16A-16C.

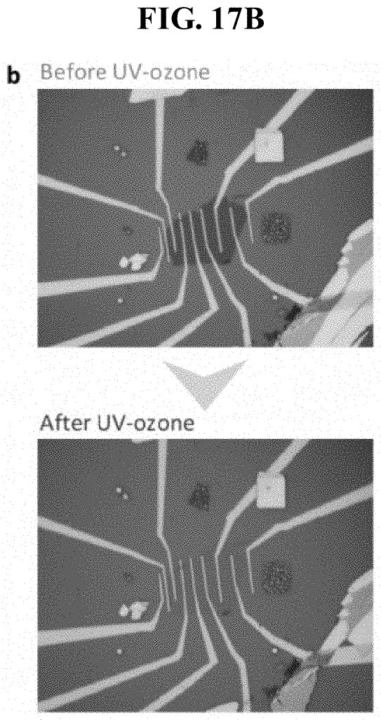

SWCNT were grown on a SiO₂/Si substrate and contacts were fabricated. The device was measured and then a monolayer of WSe₂ was dry-transferred on top of the entire structure, which was subsequently oxidized as depicted in the inset of FIG. 16A. FIGS. 17A-17B show scanning electron microscope (SEM) and optical images at different stages of the device formation. The SWCNT measured before WSe₂ transfer showed p-type transistor characteristics. After WSe₂ transfer and TOS formation, however, the current is nearly constant as a function of back-gate bias do the high hole concentration induced in the SWCNT.

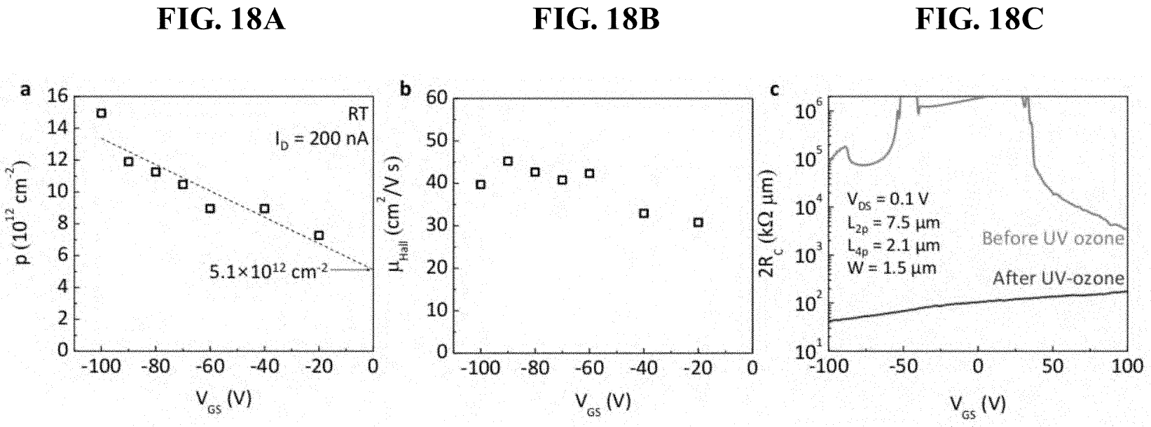

Next, a 4 L-WSe₂ device was fabricated and measured before and after UV-ozone oxidation, as shown in FIG. 16B. Before UV-ozone oxidation, the device shows n-type transistor characteristics, possibly attributed to Fermi-level pinning that takes place with conventional evaporated contacts. After UV-ozone oxidation, the WSe₂ channel thickness is reduced from 4 L to 3 L due to the formation of TOS at the surface, and the device shows resistor-like behavior due to the high hole density in the channel. The hole density and mobility extracted by Hall-effect measurements range from 7 to 15×10¹² #/cm² and from 30 to 40 cm²/(V·s), respectively, depending on the applied back-gate bias, and the contact resistance improves by over 20-fold after TOS doping (FIGS. 18A-18C).

In the third test, two devices with DNTT, a typical p-type organic semiconductor, were fabricated. One device included a layer of TOS oxide at the bottom of the channel while the other did not. As shown in FIG. 16C, the transistor characteristics are significantly improved with the TOS-doping layer resulting in much improved on/off ratio, reduced threshold voltage, and higher current compared to the device without TOS. The TOS-doped DNTT device shows transistor-like characteristics in contrast to the resistor-like characteristics seen for TOS-doped SWCNT and WSe₂. Possible reasons for this difference include the much larger thickness of DNTT (˜40 nm) and the placement of TOS on the bottom of the channel, closest to the back gate. Overall, the electrical characterization shows that TOS can universally dope a wide range of diverse semiconductor materials.

The use of monolayer TOS to achieve ultrahigh and universal p-type doping for graphene and other diverse semiconducting materials is presented herein. Monolayer TOS is formed through the gentle room-temperature UV-ozone oxidation of WSe₂, which is shown to leave the underlying layers damage-free. At zero back-gate bias, TOS-doped graphene showed very high hole doping density (3.2×10¹³ #/cm²) and low sheet resistance (118 Ω/sq.) at room temperature. By adding WSe₂ interlayers between TOS and graphene channel, the sheet resistance is further reduced (48 Ω/sq.) and the hole mobility is significantly enhanced, reaching the LA phonon-limited mobility. The low light absorption (0.67%) for λ>1200 nm demonstrates the potential of TOS-doped graphene as a transparent conductor for integrated photonic applications at telecommunication wavelengths. Finally, TOS doping of other materials, such as SWCNT, WSe₂, and DNTT demonstrate its universal doping properties and suggest its use in diverse applications, especially those where fabrication temperatures must be minimized.

### REFERENCES

[1] Wang, L. et al. One-Dimensional Electrical Contact to a Two-Dimensional Material. Science 342, 614-617 (2013).
[2] Mak, K. F. et al. Measurement of the Optical Conductivity of Graphene. Phys. Rev. Lett.
101, 196405 (2008).
[3] Bonaccorso, F., Sun, Z., Hasan, T. & Ferrari, A. C. Graphene photonics and optoelectronics. Nat. Photonics 4, 611-622 (2010).
[4] Bae, S. et al. Roll-to-roll production of 30-inch graphene films for transparent electrodes. Nat. Nanotechnol. 5, 574-578 (2010).
[5] Cao, Y. et al. Unconventional superconductivity in magic-angle graphene superlattices. Nature 556, 43-50 (2018).
[6] Cao, Y. et al. Correlated insulator behaviour at half-filling in magic-angle graphene superlattices. Nature 556, 80-84 (2018).
[7] Lu, X. et al. Superconductors, orbital magnets and correlated states in magic-angle bilayer graphene. Nature 574, 653-657 (2019).
[8] Wang, L. et al. Magic continuum in twisted bilayer WSe₂. Preprint at http://arxiv.org/abs/1910. 12147 (2019).
[9] Browning, A. et al. Evaluation of disorder introduced by electrolyte gating through transport measure-ments in graphene. Appl. Phys. Express 9, 065102 (2016).
[10] Lee, H., Paeng, K. & Kim, I. S. A review of doping modulation in graphene. Synth. Met. 244, 36-47 (2018).
[11] Akinwande, D. et al. Graphene and two-dimensional materials for silicon technology. Nature 573, 507-518 (2019).
[12] Pizzocchero, F. et al. The hot pick-up technique for batch assembly of van der Waals heterostructures. Nat. Commun. 7, 11894 (2016).
[13] Kim, D. H., Park, M. R., Lee, H. J. & Lee, G. H. Thickness dependence of electrical properties of ITO film deposited on a plastic substrate by RF magnetron sputtering. Appl. Surf. Sci. 253, 409-411 (2006).
[14] Datta, R. S. et al. Flexible two-dimensional indium tin oxide fabricated using a liquid metal printing technique. Nat. Electron. 3, 51-58 (2020).
[15] Woo, Y. Transparent Conductive Electrodes Based on Graphene-Related Materials. Micromachines 10, 13 (2018).
[16] Nipane, A. et al. Atomic Layer Etching (ALE) of WSe₂ Yielding High Mobility p-FETs. In 2019 Device Res. Conf., 2013, 231-232 (IEEE, Ann Arbor, 2019).
[17] Yamamoto, M., Nakaharai, S., Ueno, K. & Tsukagoshi, K. Self-Limiting Oxides on WSe₂ as Controlled Surface Acceptors and Low-Resistance Hole Contacts. Nano Lett. 16, 2720-2727 (2016).
[18] Smyth, C. M., Addou, R., McDonnell, S., Hinkle, C. L. & Wallace, R. M. WSe₂-contact metal interface chemistry and band alignment under high vacuum and ultra high vacuum deposition conditions. 2D Mater. 4, 025084 (2017)
[19] Greiner, M. T. & Lu, Z.-H. Thin-film metal oxides in organic semiconductor devices: their electronic structures, work functions and interfaces. NPG Asia Mater. 5, e55 (2013).
[20] Wang, H., Wu, Y., Cong, C., Shang, J. & Yu, T. Hysteresis of Electronic Transport in Graphene Transistors. ACS Nano 4, 7221-7228 (2010).
[21] Zhao, J. et al. Lithium-ion-based solid electrolyte tuning of the carrier density in graphene. Sci. Rep. 6, 1-7 (2016).
[22] Wang, M. et al. Breaking the Doping Limit in Silicon by Deep Impurities. Phys. Rev. Appl. 11, 054039 (2019).
[23] Chen, C.-F. et al. Controlling inelastic light scattering quantum pathways in graphene. Nature 471, 617-620 (2011).
[24] Romagnoli, M. et al. Graphene-based integrated photonics for next-generation datacom and telecom. Nat. Rev. Mater. 3, 392-414 (2018).
[25] Chen, J.-H., Jang, C., Xiao, S., Ishigami, M. & Fuhrer, M. S. Intrinsic and extrinsic performance limits of graphene devices on SiO2. Nat. Nanotechnol. 3, 206-209 (2008).
[26] Hwang, E. H. & Das Sarma, S. Acoustic phonon scattering limited carrier mobility in two-dimensional extrinsic graphene. Phys. Rev. B 77, 115449 (2008).
[27] Hess, L. H., Seifert, M. & Garrido, J. A. Graphene transistors for bioelectronics. Proc. IEEE 101, 1780-1792 (2013).
[28] Dankerl, M. et al. Graphene solution-gated field-effect transistor array for sensing applications. Adv. Funct. Mater. 20, 3117-3124 (2010).
[29] Zhao, J. et al. Application of sodium-ion-based solid electrolyte in electrostatic tuning of carrier density in graphene. Sci. Rep. 7, 3168 (2017).
[30] Hess, L. H. et al. High-transconductance graphene solution-gated field effect transistors. Appl. Phys. Lett. 99, 033503 (2011).
[31] Brown, M. A., Crosser, M. S., Leyden, M. R., Qi, Y. & Minot, E. D. Measurement of high carrier mobility in graphene in an aqueous electrolyte environment. Appl. Phys. Lett. 109, 093104 (2016).
[32] Eltes, F. et al. An integrated cryogenic optical modulator. Preprint at http://arxiv.org/abs/1904. 10902 (2019).
[33] Micallef, F. G. et al. Transparent conductors for Mid-infrared liquid crystal spatial light modulators. Thin Solid Films 660, 411-420 (2018).
[34] Tohsophon, T., Dabirian, A., De Wolf, S., Morales-Masis, M. & Ballif, C. Environmental stability of high-mobility indium-oxide based transparent electrodes. APL Mater. 3, 116105 (2015).
[35] Morales-Masis, M. et al. Highly Conductive and Broadband Transparent Zr-Doped In2O3 as Front Electrode for Solar Cells. IEEE J. Photovoltaics 8, 1202-1207 (2018).
[36] Tan, H. Materials and Light Management for High-Efficiency Thin-Film Silicon Solar Cells. Ph.D. thesis, Delft University of Technology (2015).
[37] Bingel, A. et al. AZO/Ag/AZO transparent conductive films: correlation between the structural, electrical, and optical properties and development of an optical model. Opt. Mater. Express 6, 3217 (2016).
[38] Li, Y. et al. Measurement of the optical dielectric function of monolayer transition-metal dichalcogenides: MoS2, MoSe2, WS2, and WSe₂. Phys. Rev. B 90, 1-6 (2014).
[39] Frisenda, R. et al. Micro-reflectance and transmittance spectroscopy: a versatile and powerful tool to characterize 2D materials. J. Phys. D. Appl. Phys. 50, 074002 (2017).
[40] Datta, I., Phare, C. T., Dutt, A., Mohanty, A. & Lipson, M. Integrated Graphene Electro-Optic Phase Modulator. In Conf. Lasers Electro-Optics, STu3N.5 (OSA, Washington, D.C., 2017).
[41] Sorianello, V. et al. Graphene-silicon phase modulators with gigahertz bandwidth. Nat. Photonics 12, 40-44 (2018).
[42] Kim, C. et al. Fermi Level Pinning at Electrical Metal Contacts of Monolayer Molybdenum Dichalcogenides. ACS Nano 11, 1588-1596 (2017).
[43] Liu, Y. et al. Approaching the Schottky-Mott limit in van der Waals metal-semiconductor junctions. Nature 557, 696-700 (2018).
[44] Jung, Y. et al. Transferred via contacts as a platform for ideal two-dimensional transistors. Nat. Electron. 2, 187-194 (2019).

### Example 2. Methods for Producing and Assessing TOS Dopant Capabilities

The following methods were used in the experiments discussed in Example 1.

### Fabrication and Characterization of Graphene Device

WSe₂, graphene, and h-BN flakes were prepared on SiO₂/Si substrate by mechanical exfoliation. The thickness of each flake was determined by the contrast difference in optical microscopic images. Only monolayer graphene was used while the WSe₂ thickness varied from 1 L to 5 L to see the layer dependence for this study. The stacking of flakes was conducted by the dry transfer method using PCL polymer at 5058° C. to pick up flakes that are then transferred onto a 285-nm SiO₂/Si at 80° C. to melt the polymer. To remove the polymer, the sample was annealed at 340° C. under vacuum condition. Edge contacts were formed to the graphene layer by etching through the layers and subsequently depositing e-beam evaporated metal. Cr/Au (2/80 nm) contacts were deposited by e-beam evaporation after reactive-ion etching (RIE) of the WSe₂ and graphene layers with CHF₃ to form an edge contact. UV-ozone oxidation (Samco UV-2) was conducted at room temperature for 30 minutes with an oxygen flow rate of 3 L/min. The etch to remove TOS was conducted using 1M KOH diluted in deionized water followed by a deionized water rinse and vacuum annealing at 300° C. Electrical measurements were performed with both a semiconductor parameter analyzer (Keysight B1500A) and a lock-in amplifier connected to a cryostat containing a tunable perpendicular magnetic field under vacuum conditions.

### Fabrication of SWCNT, WSe₂, and DNTT Devices

SWCNT device: CNTs were grown on a SiO₂/Si substrate at 890° C. The locations of SWCNTs were identified using SEM and AFM scans. Cr/Pd (2/20 nm) contacts were then fabricated on selected SWCNTs using the lift-off method. 1 L-WSe₂ was transferred and subsequently oxidized after the initial electrical measurements of the SWCNT (without TOS) were completed.

WSe₂ device: 4 L-WSe₂ was stacked on h-BN using the same dry-transfer process used with graphene. E-beam evaporation and lift-off was used to create top surface contacts of Pd/Au (20/50 nm) to WSe₂. Electrical measurements of the same device before and after UV-ozone oxidation are presented in the manuscript.

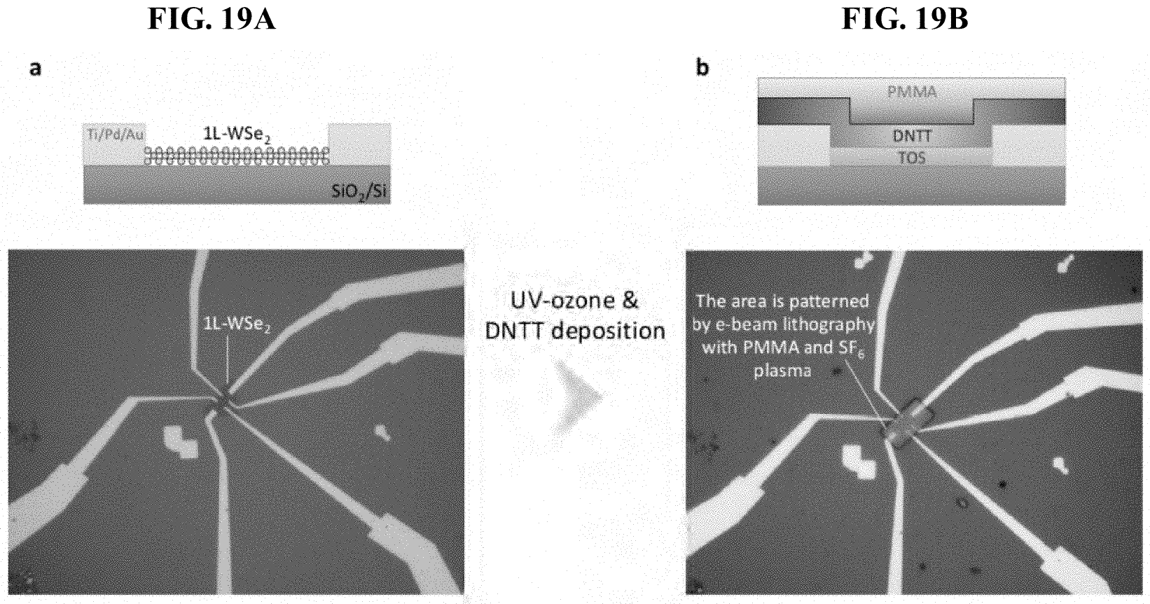

DNTT device: Two devices were made on the same chip, one with and one without TOS. First, 1 L-WSe₂ was exfoliated on a SiO₂/Si substrate followed by lift-off metallization with Ti/Pd/Au (2/20/20 nm). 1 L-WSe₂ was converted into monolayer TOS through UV-ozone oxidation. Contacts were also concurrently patterned in areas without TOS to form the second device. Then, 40 nm of DNTT was deposited by sublimation. The channel areas were defined by coating the sample with PMMA, patterning with e-beam lithography, and etching away the semiconductor with SF₆ plasma, leaving the active channel area (see FIGS. 19A and 19B).

### Absorption Spectrum Measurements

The absorption spectrum of CVD-grown 1 L-WSe₂ on 1 L-graphene directly on quartz (purchased from 2D Semiconductors) was obtained by differential reflectance measurements. The sample was placed onto a quartz substrate. For this measurement, h-BN was not used to avoid any optical interference. The absorption was calculated by the equation when sample thickness d<<λ, of normal light incidence,

$$( \frac{{R}_{s + q} - {R}_{q}}{{R}_{q}} ) = ( \frac{4}{{n}_{q}^{2} - 1} ) A$$

Here, R_{s+q} is the reflection from the sample on quartz, R_{q} is the reflection from the quartz substrate, n_{q} is the refractive index of the quartz, and A is the absorption. To minimize environmental effects, the reflection was measured under vacuum condition. Incident super-continuum laser is passed through a monochromator to select the wavelength of light. The monochromatic light was incident on the sample using a high NA microscope objective, resulting in a spot size of no more than 15 μm over the entire spectrum (700 to 1700 nm). The slit width was chosen so that the optical bandwidth was much smaller (<0.5 nm) than the wavelength sweep (5 nm). Optical low-pass filters at 650, 950 and 1250 nm were used to block light harmonics of the incoming wavelength and increase signal-to-noise at the detector. The reflected light was collected through the same microscope objective that excited the sample and sent to an InGaAs photodetector connected to a lock-in amplifier synchronized with a chopper operating at 499 Hz frequency, using a beam splitter.

### Damage Free Layer-by-Layer Etching Process

The optical microscopic images of WSe₂ for each process for a layer-by-layer etching process are shown in FIG. 2. 1 L-WSe₂ becomes barely visible after UV-ozone treatment due to formation of tungsten oxyselenide (TOS) while 2 L and 4 L are still clearly visible indicating underlying layers are not oxidized. After a KOH rinse for 10-seconds, each flake is one-layer thinned (e.g., 2 L becomes 1 L). It is indicative of self-limited oxidation (only topmost layer is oxidized) and damage-free layer-by-layer etching. It motivates the high quality doping technique using TOS by UV-ozone treatment. These can be repeated a few more cycles for clean layer-by-layer etching process.

FIGS. 6A-6C show transmission electron microscope (TEM) and selected area electron diffraction (SAED) pattern images for monolayer and few-layer WSe₂. The monolayer WSe₂ became an amorphous state after UV-ozone treatment while few-layer (3 5 layers) WSe₂ still showed single crystalline patterns. This indicates that the underlying layers are still intact due to the self-limited oxidation. Table 1 is the atomic percentage of WSe₂ after UV-ozone treatment obtained by energy-dispersive X-ray spectroscopy (EDS). It is noted that the atomic ratio of W and Se is approximately 1:2 for the few-layer WSe₂ since the underlying layers are preserved while the atomic percentage of Se for monolayer is significantly reduced (although not completely removed and therefore, denoted as TOS) by the oxidation process. Negligible hysteresis in the transfer curves after UV-ozone in FIGS. 9 and 10A-10C further corroborates the claim of a clean surface. With this damage-free oxidation process followed by a clean surface, TOS provides high quality p-doping with remarkably high mobility and low sheet resistance as shown in FIGS. 11A-11B and mobility comparison of FIGS. 12A-12B.

### Stability of TOS Doping

Stability in terms of temperature and retention time is of great interest in electronic and photonic applications. Devices operating at cryogenic temperatures less than 4 K has a potential to be integrated in quantum systems, including for quantum computing. A hole density (p) of TOS-doped graphene was measured at low temperature (1.5 K) by Hall measurements as shown in FIG. 13A. The density is similar to that obtained at room temperature indicating that the doping effect remains active. The Hall mobility (Hall) is dramatically improved over 100,000 cm²/(V·s) as shown in FIG. 13B due to a reduced phonon scattering. It also proves that the charge impurity scattering is sufficiently low with TOS layer to realize high speed electronics.

The hydrophilic nature of TOS makes it unstable in presence of moisture and to long-term air exposure. To resolve the issue, PMMA was spin-coated as a passivation layer on top of the TOS-doped graphene. As shown in FIG. 14, the hole density was well preserved for 4 weeks showing a slight reduction from 7 to 6×10¹² #/cm². This shows that the passivation works well against degradation due to environmental effects.

### REFERENCES

[1] Nipane, A. et al. Atomic Layer Etching (ALE) of WSe₂ Yielding High Mobility p-FETs. In 2019 Device Res. Conf., 2013, 231-232 (IEEE, Ann Arbor, 2019).
[2] Wang, L. et al. One-Dimensional Electrical Contact to a Two-Dimensional Material. Science 342, 614-617 (2013).
[3] Eltes, F. et al. An integrated cryogenic optical modulator. Preprint at http://arxiv.org/abs/1904. 10902 (2019).
[4] Yamamoto, M., Nakaharai, S., Ueno, K. & Tsukagoshi, K. Self-Limiting Oxides on WSe₂ as Controlled Surface Acceptors and Low-Resistance Hole Contacts. Nano Lett. 16, 2720-2727 (2016).

### Example 3. Optical Response of TOS-Doped Semiconductors

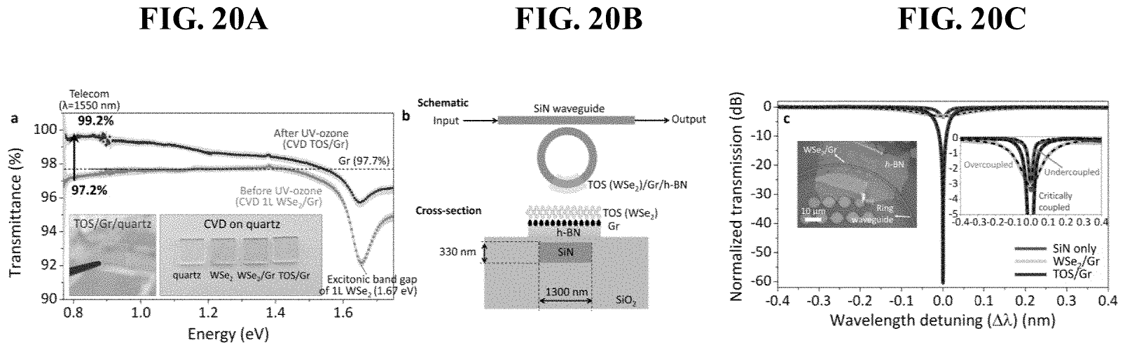

One advantage of the doping technique is the ability to strongly modify the interband absorption spectra of graphene for photon energies up to 2E_{F} due to Pauli blocking. FIG. 20A shows the transmittance of chemical vapor deposition (CVD)-grown 1 L-WSe₂/graphene films on quartz before and after UV-ozone oxidation. Before oxidation, the transmittance spectrum shows an absorption peak at 1.67 eV that corresponds to the excitonic bandgap of WSe₂. As expected, the transmittance remains around graphene's intrinsic value (97.7%) for photon energies less than 1.4 eV since the top WSe₂ is transparent in the near-IR region. In contrast, the transmittance significantly improves after oxidation in the regime of interest (>99%). Specifically, the TOS doping increases the transmittance to 99.2% at telecommunication wavelengths (λ˜1550 nm), demonstrating its potential as a transparent conductor for near-IR photonic applications. From the transmittance data, it can be inferred that E_{F} of ˜0.6 eV for the TOS-doped graphene, in reasonable agreement with that from electrically measurements for exfoliated sample discussed above (0.65 eV). Furthermore, the TOS-doped graphene is highly transparent even in the visible regime indicated by the reduction of the WSe₂ absorption peak. Note that the weak presence of the excitonic peak is indicative of the thickness inhomogeneity in the top CVD-grown WSe₂ layer within the area of illumination.

To further demonstrate the ability to integrate the TOS-doped graphene as a transparent gate electrode and high-speed phase-modulator in photonic circuits for near-IR applications, the optical response of TOS-doped graphene embedded on planarized low loss silicon nitride (SiN) waveguides was probed, in a microring resonator cavity (FIG. 20B). Notably, the planar photonic structure comprises the TOS/Gr/h-BN/SiN composite waveguide with a strong optical mode overlap when compared to out-of-plane measurements. The normalized ring transmission spectra show that the bare low-loss cavity is weakly coupled to the straight waveguide (under-coupled regime), thereby showing a low extinction of ˜3 dB at resonance wavelength with narrow linewidth (FIG. 20C). After the transfer of WSe₂/Gr/h-BN on the planarized SiN substrate, an insertion loss of 0.077±0.014 dB/μm in the composite waveguide was extracted from the optical response as shown in gray of FIG. 20C. The high insertion loss can be attributed to the undoped graphene in WSe₂/Gr/h-BN stack, which causes the resonator linewidth to broaden considerably, increasing the cavity loss, thereby over coupling the waveguide to the cavity. Interestingly, the insertion loss is lowered by about 85% to 0.012±0.0022 dB/μm after UV-ozone oxidation. As aforementioned, the low propagation loss can be attributed to Pauli blocking in TOS-doped graphene, which causes the graphene to become optically transparent with minimal intraband loss contribution. The significant lowering of insertion loss leads to the condition where the coupling rate between waveguide and ring resonator equals the optical decay rate (loss) in the cavity, thereby exhibiting a critically coupled resonance transmission response (shown in red in FIG. 20C), where the extinction is ˜60 dB, with the spectral sharpening of the resonance. The 2% change measured in the out-of-plane transmission (FIG. 20A) is magnified to an 85% change in the in-plane transmission due to the enhanced optical mode overlap in integrated photonic circuits.

In addition to the various embodiments depicted and claimed, the disclosed subject matter is also directed to other embodiments having other combinations of the features disclosed and claimed herein. As such, the particular features presented herein can be combined with each other in other manners within the scope of the disclosed subject matter such that the disclosed subject matter includes any suitable combination of the features disclosed herein.

The foregoing description of specific embodiments of the disclosed subject matter has been presented for purposes of illustration and description. It is not intended to be exhaustive or to limit the disclosed subject matter to those embodiments disclosed.

It will be apparent to those skilled in the art that various modifications and variations can be made in the methods and systems of the disclosed subject matter without departing from the spirit or scope of the disclosed subject matter. Thus, it is intended that the disclosed subject matter include modifications and variations that are within the scope of the appended claims and their equivalents.

What is claimed is:

1. A semiconductor comprising a tungsten oxyselenide (TOS) p-type dopant.

2. The semiconductor of claim 1, wherein the TOS is formed by:
(a) introducing a layer of tungsten selenide (WSe₂) to the semiconductor; and
(b) oxidizing the layer of tungsten selenide to produce a layer of TOS.

3. The semiconductor of claim 2, wherein the oxidizing is performed at room temperature.

4. The semiconductor of claim 2, wherein the oxidizing comprises UV-ozone oxidation.

5. The semiconductor of claim 2, wherein the oxidizing is configured to avoid damage to the semiconductor.

6. The semiconductor of claim 1, wherein the layer of TOS is a monolayer.

7. The semiconductor of claim 1, wherein the TOS is a p-type surface-layer dopant.

8. The semiconductor of claim 1, wherein the semiconductor is a 1D semiconductor, a 2D semiconductor, or a 3D semiconductor.

9. The semiconductor of claim 1, wherein the semiconductor is graphene, carbon nanotube, 4 L-tungsten diselenide, or dinaphthothienothiphene (DNTT).

10. A method of doping a semiconductor, the method comprising:
(a) providing the semiconductor;
(b) introducing a layer of tungsten selenide (WSe₂) to the semiconductor; and
(c) oxidizing the layer of tungsten selenide to produce a layer of tungsten oxyselenide (TOS).

11. The method of claim 10, wherein the oxidizing is performed at room temperature.

12. The method of claim 10, wherein the oxidizing comprises UV-ozone oxidation.

13. The method of claim 10, wherein the oxidizing is configured to avoid damage to the semiconductor.

14. The method of claim 10, wherein the layer of TOS is a monolayer.

15. The method of claim 10, wherein the TOS is a p-type surface-layer dopant.

16. The method of claim 10, wherein the semiconductor is a 1D semiconductor, a 2D semiconductor, or a 3D semiconductor.

17. The method of claim 10, wherein the semiconductor is graphene, carbon nanotube, 4 L-tungsten diselenide, or dinaphthothienothiphene (DNTT).
